(19) United States
(12) Patent Application Publication
(10) Pub. No.: US 2026/0133616 A1
(43) Pub. Date: May 14, 2026

(54) SYSTEMS AND METHODS FOR POWER REDUCTION WITH DIE-TO-DIE (D2D) COMMUNICATIONS

(71) Applicant: Samsung Electronics Co., Ltd., Suwon-si (KR)

(72) Inventors: Soon Ju Kim, San Jose, CA (US); Hyoun Kwon Jeong, Pleasanton, CA (US); Soogil Jeong, Pleasanton, CA (US)

(21) Appl. No.: 19/313,788

(22) Filed: Aug. 28, 2025

Related U.S. Application Data
(60) Provisional application No. 63/719,010, filed on Nov. 11, 2024.

(51) Int. Cl. G06F 1/3234; G06F 13/42; H01L 23/538

(52) U.S. Cl. CPC G06F 1/3234; G06F 13/42; H10W 70/60; H10W 70/611

(57) ABSTRACT

Provided is a method for die-to-die (D2D) communications, the method including receiving, by a processing circuit, a flow control unit (FLIT) header including a mode indicator, determining, by the processing circuit and based on the mode indicator, to operate the processing circuit in an active idle mode for a first data portion associated with the FLIT header, and operating, by the processing circuit, in the active idle mode.

### CROSS-REFERENCE TO RELATED APPLICATION(S)

This application claims priority to, and benefit of, U.S. Provisional Application Ser. No. 63/719,010, filed on Nov. 11, 2024, and entitled “POWER REDUCTION SCHEME DIE-TO-DIE (D2D) COMMUNICATION,” the entire content of which is incorporated herein by reference.

### FIELD

Aspects of some embodiments of the present disclosure relate to systems and methods for enabling a power reduction scheme with die-to-die (D2D) communications.

### BACKGROUND

In the field of computers, a computing system may include multiple processing units connected to (e.g., communicatively coupled to) each other and/or connected to one or more memories. The processing units and/or memories may be associated with respective dies and may be connected over one or more D2D interfaces. Such computing systems have become increasingly popular, in part, for allowing communications (e.g., commands and data) to be distributed among the processing units and/or the memories. Improvements to D2D communications can significantly improve the performance of computing systems.

The present background section is intended to provide context only, and the disclosure of any embodiment or concept in this section does not constitute an admission that said embodiment or concept is prior art.

### SUMMARY

Aspects of some embodiments of the present disclosure are directed to improved systems and methods for D2D communications with a power reduction scheme for a reduced power consumption.

According to some embodiments of the present disclosure, there is provided a method for die-to-die (D2D) communications including receiving, by a processing circuit, a flow control unit (FLIT) header including a mode indicator, determining, by the processing circuit and based on the mode indicator, to operate the processing circuit in an active idle mode for a first data portion associated with the FLIT header, and operating, by the processing circuit, in the active idle mode.

The operating in the active idle mode may include operating a physical-layer circuit of the processing circuit at a reduced power consumption level based on a scrambler circuit or an analog front-end (AFE) circuit of the physical-layer circuit.

The operating in the active idle mode may include sending, to a physical-layer circuit, information indicating that the first data portion includes non-valid data.

The mode indicator may correspond to one or more bit positions in the FLIT header.

The mode indicator may be encoded by two bit positions in the FLIT header, and the first data portion may correspond to all data chunks associated with the FLIT header.

The FLIT header may be a 68-byte unit FLIT header, and the first data portion may correspond to 64 bytes of data associated with the FLIT header.

The mode indicator may be encoded by three bit positions in the FLIT header, and the first data portion may correspond to a first half of all data chunks associated with the FLIT header.

A first state of a first bit position of the three bit positions may indicate a location of the first data portion.

A first state of a first bit position of the three bit positions may indicate that the processing circuit is to operate in the active idle mode for the first half of all the data chunks associated with the FLIT header, and a second state of the first bit position of the three bit positions may indicate that the processing circuit is to operate in the active idle mode for a second half of all the data chunks associated with the FLIT header.

The FLIT header may be a 256-byte unit FLIT header, and the first data portion may correspond to 124 bytes of data associated with the FLIT header.

According to some other embodiments of the present disclosure, there is provided a system for die-to-die (D2D) communications including a first die, and a second die connected to the first die, wherein the first die is configured to perform receiving, by a processing circuit of the first die, a flow control unit (FLIT) header including a mode indicator, determining, by the processing circuit of the first die and based on the mode indicator, to operate the processing circuit in an active idle mode for a first data portion associated with the FLIT header, and operating, by the processing circuit, in the active idle mode.

The operating in the active idle mode may include operating a physical-layer circuit of the processing circuit at a reduced power consumption level based on a scrambler circuit or an analog front-end (AFE) circuit of the physical-layer circuit.

The operating in the active idle mode may include sending, to a physical-layer circuit, information indicating that the first data portion includes non-valid data.

The mode indicator may correspond to one or more bit positions in the FLIT header.

The mode indicator may be encoded by two bit positions in the FLIT header, and the first data portion may correspond to all data chunks associated with the FLIT header.

The mode indicator may be encoded by three bit positions in the FLIT header, and the first data portion may correspond to a first half of all data chunks associated with the FLIT header.

A first state of a first bit position of the three bit positions may indicate that the processing circuit of the first die is to operate in the active idle mode for the first half of all the data chunks associated with the FLIT header, and a second state of the first bit position of the three bit positions may indicate that the processing circuit of the first die is to operate in the active idle mode for a second half of all the data chunks associated with the FLIT header.

According to some other embodiments of the present disclosure, there is provided a device for die-to-die (D2D) communications including a processing circuit, and a memory storing instructions that, based on being executed by the processing circuit, cause the processing circuit to perform receiving, by the processing circuit, a flow control unit (FLIT) header including a mode indicator, determining, by the processing circuit and based on the mode indicator, to operate the processing circuit in an active idle mode for a first data portion associated with the FLIT header, and operating, by the processing circuit, in the active idle mode.

The operating in the active idle mode may include operating a physical-layer circuit of the processing circuit at a reduced power consumption level based on a scrambler circuit or an analog front-end (AFE) circuit of the physical-layer circuit.

The operating in the active idle mode may include sending, to a physical-layer circuit, information indicating that the first data portion includes non-valid data.

### BRIEF DESCRIPTION OF THE DRAWINGS

Non-limiting and non-exhaustive embodiments of the present disclosure are described with reference to the following figures, wherein like reference numerals refer to like parts throughout the various views unless otherwise specified.

FIG. 1 is a block diagram depicting a system for D2D communications, according to some embodiments of the present disclosure.

FIG. 2 is a block diagram depicting components of a processing circuit for D2D communications, according to some embodiments of the present disclosure.

FIG. 3A is a diagram depicting a first type of header (e.g., a first modified header) for processing data in the system for D2D communications, according to some embodiments of the present disclosure.

FIG. 3B is a diagram depicting multiple headers of the first type of header and their corresponding data portions (e.g., data chunks), according to some embodiments of the present disclosure.

FIG. 4A is a diagram depicting a second type of header (e.g., a second modified header) for processing data in the system for D2D communications, according to some embodiments of the present disclosure.

FIG. 4B is a diagram depicting a header of the second type of header and its corresponding data portions (e.g., data chunks), according to some embodiments of the present disclosure.

FIG. 5 is a flowchart depicting operations of a method for D2D communications, according to some embodiments of the present disclosure.

Corresponding reference characters indicate corresponding components throughout the several views of the drawings. Skilled artisans will appreciate that elements in the figures are illustrated for simplicity and clarity, and have not necessarily been drawn to scale. For example, the dimensions of some of the elements, layers, and regions in the figures may be exaggerated relative to other elements, layers, and regions to help to improve clarity and understanding of various embodiments. Also, common but well-understood elements and parts not related to the description of the embodiments might not be shown to facilitate a less obstructed view of these various embodiments and to make the description clear.

### DETAILED DESCRIPTION

Aspects of the present disclosure and methods of accomplishing the same may be understood more readily by reference to the detailed description of one or more embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that this disclosure will be thorough and complete, and will fully convey aspects of the present disclosure to those skilled in the art. Accordingly, description of processes, elements, and techniques that are not necessary to those having ordinary skill in the art for a complete understanding of the aspects and features of the present disclosure may be omitted.

Unless otherwise noted, like reference numerals, characters, or combinations thereof denote like elements throughout the attached drawings and the written description, and thus, descriptions thereof will not be repeated. Skilled artisans will appreciate that elements in the figures are illustrated for simplicity and clarity, and have not necessarily been drawn to scale. For example, the dimensions of some of the elements, layers, and regions in the figures may be exaggerated relative to other elements, layers, and regions to help to improve clarity and understanding of various embodiments. Also, common but well-understood elements and parts not related to the description of the embodiments might not be shown to facilitate a less obstructed view of these various embodiments and to make the description clear.

In the detailed description, for the purposes of explanation, numerous specific details are set forth to provide a thorough understanding of various embodiments. It is apparent, however, that various embodiments may be practiced without these specific details or with one or more equivalent arrangements.

It will be understood that, although the terms “zeroth,” “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or component is referred to as being “on,” “connected to,” or “coupled to” another element or component, it can be directly on, connected to, or coupled to the other element or component, or one or more intervening elements or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or component is referred to as being “between” two elements or components, it can be the only element or component between the two elements or components, or one or more intervening elements or components may also be present.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, each of the terms “or” and “and/or” includes any and all combinations of one or more of the associated listed items. For example, the expression “A and/or B” denotes A, B, or A and B.

For the purposes of this disclosure, expressions such as “at least one of,” when preceding a list of elements, modify the entire list of elements and do not modify the individual elements of the list. For example, “at least one of X, Y, or Z,” “at least one of X, Y, and Z,” and “at least one selected from the group consisting of X, Y, and Z” may be construed as X only, Y only, Z only, or any combination of two or more of X, Y, and Z, such as, for instance, XYZ, XYY, YZ, and ZZ.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Any of the components or any combination of the components described (e.g., in any system diagrams included herein) may be used to perform one or more of the operations of any flow chart included herein. Further, (i) the operations are merely examples, and may involve various additional operations not explicitly covered, and (ii) the temporal order of the operations may be varied.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Any of the functionalities described herein, including any of the functionalities that may be implemented with a host, a device, and/or the like or a combination thereof, may be implemented with hardware, software, firmware, or any combination thereof including, for example, hardware and/or software combinational logic, sequential logic, timers, counters, registers, state machines, volatile memories such as dynamic RAM (DRAM) and/or static RAM (SRAM), nonvolatile memory including flash memory, persistent memory such as cross-gridded nonvolatile memory, memory with bulk resistance change, phase change memory (PCM), and/or the like and/or any combination thereof, complex programmable logic devices (CPLDs), field programmable gate arrays (FPGAs), application-specific ICs (ASICs), central processing units (CPUs) including complex instruction set computer (CISC) processors and/or reduced instruction set computer (RISC) processors, graphics processing units (GPUs), neural processing units (NPUs), tensor processing units (TPUs), data processing units (DPUs), and/or the like, executing instructions stored in any type of memory. In some embodiments, one or more components may be implemented as a system-on-a-chip (SoC).

Any of the computational devices disclosed herein may be implemented in any form factor, such as 3.5 inch, 2.5 inch, 1.8 inch, M.2, Enterprise and Data Center Standard Form Factor (EDSFF), NF1, and/or the like, using any connector configuration such as Serial Advanced Technology Attachment (SATA), Small Computer System Interface (SCSI), Serial Attached SCSI (SAS), U.2, and/or the like. Any of the computational devices disclosed herein may be implemented entirely or partially with, and/or used in connection with, a server chassis, server rack, data room, data center, edge data center, mobile edge data center, and/or any combinations thereof.

Any of the devices disclosed herein that may be implemented as storage devices may be implemented with any type of nonvolatile storage media based on solid-state media, magnetic media, optical media, and/or the like. For example, in some embodiments, a storage device (e.g., a computational storage device) may be implemented as an SSD based on not-AND (NAND) flash memory, persistent memory such as cross-gridded nonvolatile memory, memory with bulk resistance change, PCM, and/or the like, or any combination thereof.

Any of the communication connections and/or communication interfaces disclosed herein may be implemented with one or more interconnects, one or more networks, a network of networks (e.g., the Internet), and/or the like, or a combination thereof, using any type of interface and/or protocol. Examples include Peripheral Component Interconnect Express (PCIe), non-volatile memory express (NVMe), NVMe-over-fabric (NVMe-oF), Ethernet, Transmission Control Protocol/Internet Protocol (TCP/IP), Direct Memory Access (DMA) Remote DMA (RDMA), RDMA over Converged Ethernet (ROCE), FibreChannel, InfiniBand, SATA, SCSI, SAS, Internet Wide Area RDMA Protocol (iWARP), and/or a coherent protocol, such as Compute Express Link (CXL), CXL. mem, CXL. cache, CXL. IO and/or the like, Gen-Z, Open Coherent Accelerator Processor Interface (OpenCAPI), Cache Coherent Interconnect for Accelerators (CCIX), and/or the like, Advanced eXtensible Interface (AXI), any generation of wireless network including 2G, 3G, 4G, 5G, 6G, and/or the like, any generation of Wi-Fi, Bluetooth, near-field communication (NFC), and/or the like, or any combination thereof.

In some embodiments, a software stack may include a communication layer that may implement one or more communication interfaces, protocols, and/or the like such as PCIe, NVMe, CXL, Ethernet, NVMe-oF, TCP/IP, and/or the like, to enable a host and/or an application running on the host to communicate with a computational device or a storage device.

Each of the terms “processing circuit” and “means for processing” is used herein to mean any suitable combination of hardware, firmware, and software, employed to process data or digital signals. Processing circuit hardware may include, for example, application specific integrated circuits (ASICs), general purpose or special purpose central processing units (CPUs), digital signal processors (DSPs), graphics processing units (GPUs), and programmable logic devices such as field programmable gate arrays (FPGAs). In a processing circuit, as used herein, each function is performed either by hardware configured, i.e., hard-wired, to perform that function, or by more general-purpose hardware, such as a CPU, configured to execute instructions stored in a non-transitory storage medium. A processing circuit may be fabricated on a single printed circuit board (PCB) or distributed over several interconnected PCBs. A processing circuit may contain other processing circuits; for example, a processing circuit may include two processing circuits, an FPGA and a CPU, interconnected on a PCB. In some embodiments one or more processing circuits may be included in one or more dies (e.g., on a die level) for performing D2D communications.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As mentioned above, in the field of computers, a computing system may include multiple processing units connected to (e.g., communicatively coupled to) each other and/or connected to one or more memories. The processing units and/or memories may be associated with (e.g., may be located on) respective dies and may be connected over one or more D2D interfaces. Such computing systems have become increasingly popular, in part, for allowing communications (e.g., commands and data) to be distributed among (e.g., sent between) the processing units and/or the memories. Improvements to D2D communications can significantly improve the performance of computing systems.

D2D-communications protocols may operate based on data provided by a protocol layer (also referred to as a transaction layer) of a given die. The data may be provided, in accordance with a particular format (e.g., a particular protocol), to a processing circuit of the given die. For example, the data may include header information associated with (e.g., followed by) data portions (e.g., portions of a data payload) that are referred to by the header information. The data portions may be provided in data chunks. For example, a given header may refer to a given number of data chunks. As used herein, a “data chunk” refers to a unit of data, within a data payload, having a fixed size. For example, each data chunk in a given payload may have the same size as every other data chunk in the given payload. In other words, each data chunk may have a same specific size (e.g., 64 bytes (B) or 62 B). In some situations, some data chunks may include valid data that is useful for processing by a processing circuit of the die, and some data chunks may include non-valid data (also referred to as invalid data) that is not useful for processing by the processing circuit of the die. In some systems, there is no mechanism for indicating that certain data chunks include non-valid data. Thus, power may be wasted by having the processing circuit remain in a fully active state to process the non-valid data.

Universal chiplet interconnect express (UCIe) is an example of a D2D-communication protocol. In UCIe, data may be provided in a flow control unit (FLIT) format. While a “valid” signal may be used, in UCIe, to control data toggling to achieve power savings, the unit size is fixed (e.g., is fixed at 256 B). Thus, control of data toggling with the valid signal may not be exercised at smaller sizes than 256 B. For example, the valid signal may not be used to control data toggling at a granularity of 128 B units or 64 B units.

Aspects of some embodiments of the present disclosure may enable determining a data toggle unit at, for example, a 128 B granularity (e.g., in a low-latency FLIT mode), and/or a 64 B granularity for a 68 B FLIT mode. In some embodiments, the ability to determine the data toggle unit at a finer level of granularity (e.g., at 64-byte granularity or at 128-byte granularity) may enable power saving benefits in some die components (e.g., in a buffer die using DRAM, such as in a high-bandwidth memory (HBM)) for FLIT-based D2D communication.

Aspects of some embodiments of the present disclosure provide for systems and methods for changing a state (e.g., an operation) of physical-layer components (e.g., physical-layer circuits) to save power based on information specified in a data header.

Aspects of some embodiments of the present disclosure provide for systems and methods for using a modified FLIT header to indicate when one or more physical-layer components are to enter a power-saving mode (e.g., an active idle mode). In other words, aspects of embodiments of the present disclosure allow for support of a FLIT-based active idle mode in D2D communications.

Aspects of some embodiments of the present disclosure provide for systems and methods for indicating which data chunks should be associated with the power-saving mode (e.g., with the active idle mode).

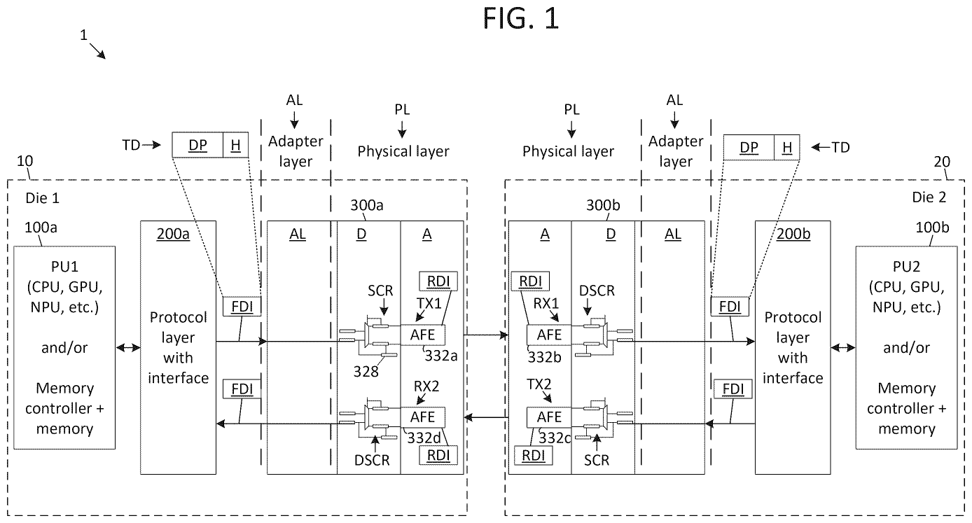

FIG. 1 is a block diagram depicting a system 1 for die-to-die (D2D) communications, according to some embodiments of the present disclosure.

Referring to FIG. 1, the system 1 may include a first die 10 (e.g., a main die or a transmitter die) and a second die 20 (e.g., a secondary die or a receiver die). The first die 10 may include a first processing unit (PU1) 100a (e.g., a CPU, GPU, NPU, TPU, and/or the like) and/or a memory controller and memory. The first die 10 may include a first protocol layer 200a with an interface and a first processing circuit 300a. The first protocol layer 200a with the interface may send communications (e.g., commands and data) from the first processing unit 100a to the first processing circuit 300a in accordance with a specific format (e.g., in accordance with a FLIT format). For example, the first protocol layer 200a with the interface may be associated with a transaction data interface (e.g., a FLIT data interface FDI) and may transmit (e.g., send) transaction data TD (e.g., FLIT data, also referred to as UCIe input data). The transaction data TD may include a header H (e.g., a FLIT header) and data portions DP (e.g., a data payload including one or more data chunks) associated with the header H.

The first processing circuit 300a may include (e.g., may be) a D2D communications circuit, such as a UCIe circuit. The first processing circuit 300a may include an adapter layer AL and a physical layer PL. The physical layer PL may include a digital layer D and an analog layer A. The adapter layer AL may generate error correction-related information (e.g., cyclic redundancy check (CRC) and/or parity information). The adapter layer AL may generate retry information. In some embodiments, the adapter layer AL may generate and send, to the physical layer PL, non-valid-data indicating information 328, indicating whether a given data portion DP includes non-valid data. A digital portion of a first transmitter TX1 (e.g., a first transmitter circuit) of the first die 10 may include a scrambler SCR (e.g., a scrambler circuit). An analog portion of the first transmitter TX1 may include a first analog front-end (AFE) circuit 332a. The scrambler SCR and the first AFE circuit 332a may be referred to as physical-layer circuits of the first processing circuit 300a. The physical layer PL may be associated with a raw data interface RDI connecting the first die 10 with the second die 20. For example, the first transmitter TX1 may send (e.g., may process and send) the transaction data TD, as raw data, to the second die 20 via the raw data interface RDI.

The first processing circuit 300a may consume power to send the raw data to the second die 20. To save power, in some embodiments, the adapter layer AL may send the non-valid-data indicating information 328 to the physical-layer circuits to cause the physical-layer circuits (of the first processing circuit 300a) to operate in a power-saving mode (e.g., in an active idle mode). For example, and as discussed in further detail below, the header H may indicate that one or more data chunks of the transaction data TD include non-valid data. The first processing circuit 300a may generate (e.g., via the adapter layer AL) the non-valid-data indicating information 328 to cause the physical-layer circuits to operate in the power-saving mode for the data chunks that include non-valid data. In some embodiments, one or more scramblers SCR may be turned on or off based on the non-valid-data indicating information 328.

One of ordinary skill in the art would understand that an active idle mode corresponds to a mode of operation that consumes less power (e.g., operates a processing circuit at a reduced power consumption level) than an active mode and more power than an idle mode. For example, the idle mode may correspond to a reset or initialization stage with both a clock and data-processing operations of the first processing circuit 300a turned off. The active mode may correspond to a fully operational mode in which both the clock and the data-processing operations of the first processing circuit 300a are turned on. The active idle mode may correspond to having the clock turned on but not providing for active processing of any functions, to save power.

The second die 20 may include similar components to those of the first die 10. For example, the second die 20 may include a second processing circuit 300b, a second protocol layer 200b with an interface, and a second processing unit (PU2) 100b (e.g., a CPU, GPU, NPU, TPU, and/or the like) and/or a memory controller and memory. As with the first processing circuit 300a, the second processing circuit 300b may include (e.g., may be) a D2D communications circuit, such as a UCIe circuit. The second processing circuit 300b may include an adapter layer AL and a physical layer PL. The physical layer PL may include a digital layer D and an analog layer A. A first receiver RX1 (e.g., a first receiver circuit) of the second processing circuit 300b may receive the raw data from the first die 10 and may generate transaction data TD for a transaction data interface (e.g., a FLIT data interface FDI) of the second die 20. For example, the second processing circuit 300b may include a second AFE circuit 332b and a de-scrambler DSCR (e.g., a de-scrambler circuit). To assist in generating the transaction data TD for the second die 20, the de-scrambler DSCR may reverse the operations of the scrambler SCR. The second die 20 may use the transaction data TD to perform operations with the second processing unit 100b and/or the memory controller and memory. For example, the second die 20 may store data associated with the transaction data TD at a memory of the second die 20 or may perform one or more computations associated with a more complex computation associated with the transaction data TD.

The second die 20 may include a second transmitter TX2 (e.g., a second transmitter circuit) that is similar to the first transmitter TX1. The first die 10 may include a second receiver RX2 (e.g., a second receiver circuit) that is similar to the first receiver RX1. For example, the second transmitter TX2 may send raw data from the second die 20 to be received by the second receiver RX2 of the first die 10.

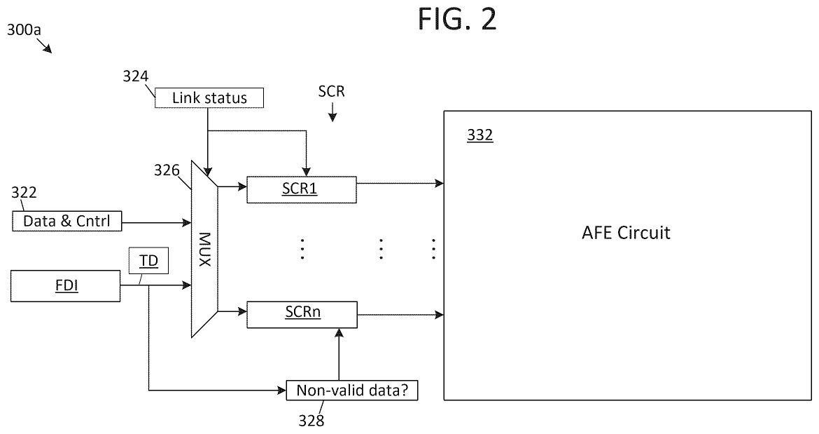

FIG. 2 is a block diagram depicting a processing circuit (e.g., portions of the first processing circuit 300a of FIG. 1) for die-to-die (D2D) communications, according to some embodiments of the present disclosure.

Referring to FIG. 2, the first processing circuit 300a may include one or more scramblers SCR (e.g., a first scrambler SCR1 through an n-th scrambler SCRn, n being an integer greater than one). As discussed above, in some embodiments, the first processing circuit 300a may receive transaction data TD. Based on the transaction data TD, the first processing circuit 300a may generate non-valid-data indicating information 328. For example, the non-valid-data indicating information 328 may include a bit set to a first state (e.g., a “1”) to indicate that a given data chunk associated with the transaction data TD includes non-valid data or set to a second state (e.g., a “0”) to indicate that a given data chunk associated with the transaction data TD includes valid data. Based on the non-valid-data indicating information 328 indicating that the given data chunk includes non-valid data, one or more of the scramblers SCR and/or the AFE circuit 332 may operate in the active idle mode for the given data chunk, such that the active idle mode reduces a power consumed by the scramblers SCR and/or the AFE circuit 332. For example, the scramblers SCR and/or the AFE circuit 332 may not perform one or more operations on the non-valid data that they would normally perform on valid data. For example, the scramblers SCR and/or the AFE circuit 332 may be turned off for non-valid data. Accordingly, the first processing circuit 300a (e.g., the scramblers SCR and/or the AFE circuit 332) may consume less power (e.g., may operate at a reduced power consumption level) as a result of the non-valid-data indicating information 328.

In some embodiments, the transaction data TD may be FLIT data associated with a FLIT data interface FDI (e.g., for UCIe). The transaction data TD may be received by a multiplexer 326. The multiplexer 326 may receive data and control signals 322 and link status information 324. The multiplexer 326 may multiplex the transaction data TD and the data and control signals 322. Outputs of the multiplexer 326 may be provided to the scramblers SCR for sending data to the AFE circuit 332 for transmitting from the first die 10 to the second die 20 (see FIG. 1).

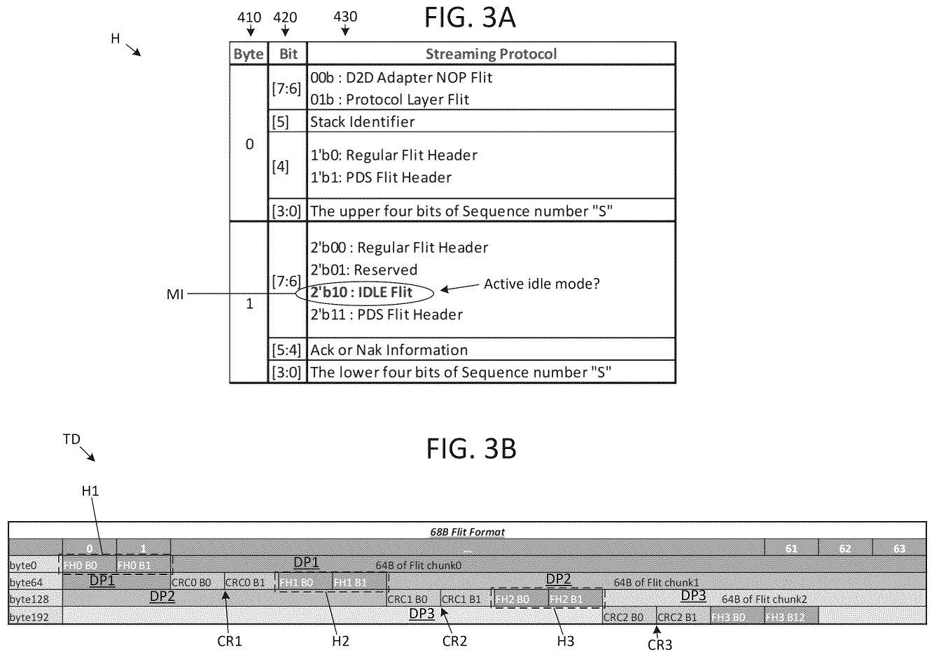

FIG. 3A is a diagram depicting a first type of header H (e.g., a first modified header) for processing data in the system 1 for die-to-die (D2D) communications, according to some embodiments of the present disclosure.

FIG. 3B is a diagram depicting multiple headers H (e.g., H1 through H3) of the first type and their corresponding data portions DP (e.g., data chunks), according to some embodiments of the present disclosure.

Referring to FIG. 3A, the header H may include a mode indicator MI (e.g., an active idle indicator). In some embodiments, the mode indicator MI may be associated with bit positions 420 (e.g., two bit positions) associated with a byte position 410 of the header H. For example, in a 68-byte unit FLIT header, the mode indicator MI may be provided by bits 6 and 7 of byte 1. For example, an encoding of “10” (e.g., one and zero) provided by bits 6 and 7 may be used to indicate that the data portion DP associated with the header H is to be treated as non-valid data. For example, the encoding of “10” from bits 6 and 7 of byte 1 of the existing 68-byte unit FLIT header may be a reserved encoding and available for use to indicate the active idle mode. In some embodiments, the bits of the header H used as the mode indicator MI may be associated with streaming-protocol information 430.

Referring to FIG. 3B, the transaction data TD for the 68-byte unit FLIT header may include a first header H1 (e.g., a first pair of a byte 0 and a byte 1 of FIG. 3A) including a mode indicator MI associated with a first data portion DP1. The first data portion DP1 may be associated with a zeroth data chunk (e.g., chunk0) having a size of 64 B. The first data portion DP1 may also be associated with first control information CR1 (e.g., two bytes of control information). Together, the first header H1, the first data portion DP1, and the control information make up the 68 B of a 68-byte unit. As used herein, a “unit” refers to a unit amount of data, including a given header H and the associated data portions DP to which the given header refers. For example, a 68-byte unit refers to header bytes, data-chunk bytes, and control information CR associated with a given header H.

The transaction data TD for the 68-byte unit FLIT header may include a second header H2 including a mode indicator MI associated with a second data portion DP2. The second data portion DP2 may be associated with a first data chunk (e.g., chunk1) having a size of 64 B. The second data portion DP2 may also be associated with second control information CR2 (e.g., two bytes of control information). The transaction data TD for the 68-byte unit FLIT header may include a third header H3 including a mode indicator MI associated with a third data portion DP3. The third data portion DP3 may be associated with a third data chunk (e.g., chunk2) having a size of 64 B. The third data portion DP3 may also be associated with third control information CR3 (e.g., two bytes of control information).

Referring to FIG. 3A and FIG. 3B, if the first header H1 has a mode indicator set to “10” (e.g., or another status for indicating an active idle mode), the processing circuit (e.g., the first processing circuit 300a of FIG. 1 by way of, at least, some of its physical-layer circuits) may enter the active idle mode for the first data portion DP1. If the second header H1 has a mode indicator not set to “10,” the processing circuit may exit active idle mode for the second data portion DP2 (e.g., may enter active mode). If the third header H3 has a mode indicator set to “10,” the processing circuit may enter active idle mode for the third data portion DP3. Accordingly, the header H may be used to indicate when the processing circuit should operate in active idle mode and save power. In the case of 68-byte units, the header H may be used to control data per 64-byte units.

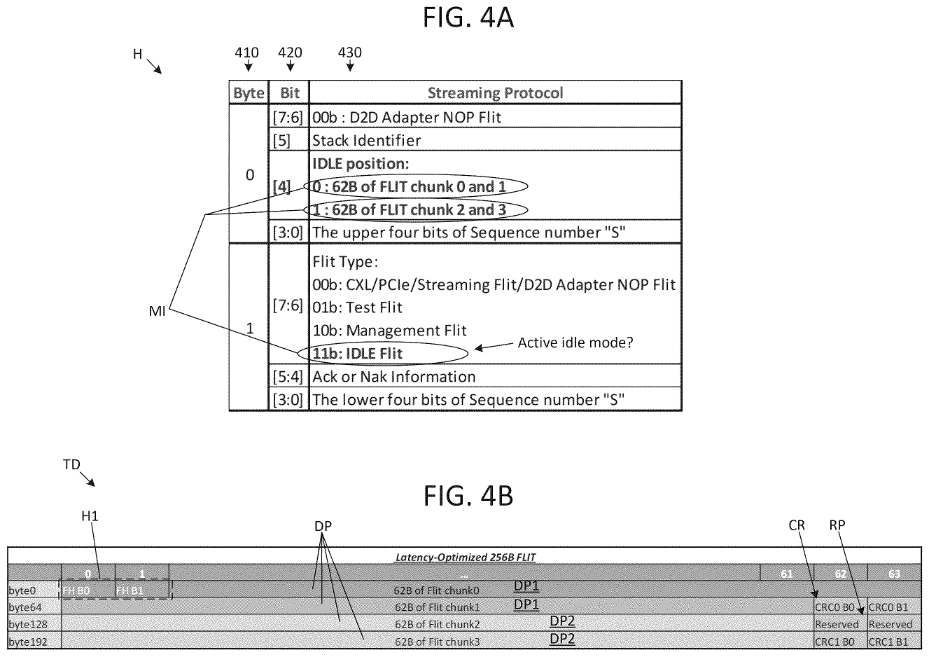

FIG. 4A is a diagram depicting a second type of header (e.g., a second modified header) for processing data in the system 1 for die-to-die (D2D) communications, according to some embodiments of the present disclosure.

FIG. 4B is a diagram depicting the header H of the second type and its corresponding data portions DP (e.g., data chunks), according to some embodiments of the present disclosure.

Referring to FIG. 4A, in some embodiments, the mode indicator MI may be associated with bit positions 420 (e.g., three bit positions) associated with one or more byte positions 410 of the header H. For example, in a 256-byte unit FLIT header, the mode indicator MI may be provided by bit 4 of byte 0 and by bits 6 and 7 of byte 1. For example, bit 4 of byte 0 may indicate a position (e.g., an active-idle position) of a relevant data portion DP associated with the header H, and bits 6 and 7 of byte 1 may indicate whether the relevant data portion DP indicated by bit 4 of byte 0 includes non-valid data.

Referring to FIGS. 4A and 4B, bit 4 of byte 0 may be set to a first state (e.g., to “0”) to indicate that a first data portion DP1 associated with two 62-byte data chunks (e.g., chunk0 and chunk1) are the relevant data portions DP referred to by bits 6 and 7 of byte 1 of the header H. On the other hand, bit 4 of byte 0 may be set to a second state (e.g., to “1”) to indicate that a second data portion DP2 associated with two other 62-byte data chunks (e.g., chunk2 and chunk3) are the relevant data portions DP referred to by bits 6 and 7 of byte 1 of the header H.

For example, if a first header H1 of the 256-byte unit includes bit 4 of byte 0 set to “1” and includes an encoding of “11” provided by bits 6 and 7 of byte 1, the first header H1 may indicate that the second data portion DP2, which corresponds to half of all data chunks associated with the first header H1 is to be treated as non-valid data. For example, the encoding of “11” from bits 6 and 7 of byte 1 of the existing 256-byte unit FLIT header may be a reserved encoding and, thus, may be available for use to indicate the active idle mode. A different encoding than “11” from bits 6 and 7 of byte 1 may indicate that the relevant data portion DP referred to by bits 6 and 7 includes valid data. In some embodiments, the bits of the header H used as the mode indicator MI may be associated with streaming-protocol information 430.

Referring to FIG. 4B, the transaction data TD for the 256-byte unit FLIT header may include the first header H1 (e.g., a first pair of a byte 0 and a byte 1 of FIG. 4A) including a mode indicator MI associated with the first data portion DP1 (chunk0 and chunk1) and the second data portion DP2 (chunk2 and chunk3). Each data chunk may have a size of 62 B. Accordingly, the first data portion DP1 may have a size of 124 B, and the second data portion DP2 may have a size of 124 B. The first data portion DP1 and the second data portion DP2 may also be associated with control information CR (e.g., four bytes of control information) and reserved portions (e.g., two bytes of reserved portions). Together, the first header H1, the first data portion DP1, the second data portion DP2, the control information CR, and the reserved portions RP make up the 256 B of the 256-byte unit. Accordingly, the header H may be used to indicate when the processing circuit should operate in active idle mode and save power. In the case of 256-byte units, the header H may be used to control data per 124-byte units (e.g., using existing reserved bits).

In some embodiments, additional RDI signals (e.g., two additional RDI signals) may be used to enable the mode indicator MI of embodiments of FIGS. 3A and 4A. For example, in some embodiments, a first RDI signal may be used for indicating whether a data portion DP includes non-valid data and a second RDI signal may be used to indicate an active-idle position. For example, when the first RDI signal indicates that the data portion DP includes non-valid data, a scrambler function may be turned off according to the active-idle position.

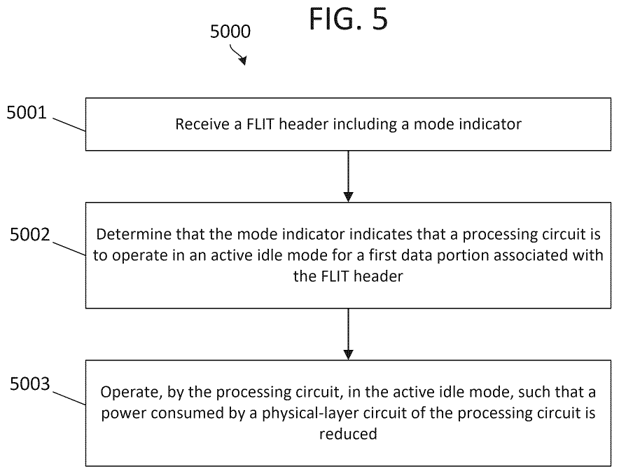

FIG. 5 is a flowchart depicting operations of a method 5000 for die-to-die (D2D) communications, according to some embodiments of the present disclosure.

Referring to FIG. 5, the method 5000 may include one or more of the following example operations. A processing circuit (e.g., the first processing circuit 300a of FIG. 1) may receive a header H (e.g., a FLIT header) including a mode indicator MI (see FIGS. 3A and 4A) (operation 5001). The processing circuit may determine that the mode indicator MI indicates that the processing circuit is to operate (e.g., is being instructed to operate) in an active idle mode for a first data portion DP (e.g., DP2 of FIG. 3B or FIG. 4B) associated with the header H (operation 5002). That is, the processing circuit may determine, based on the mode indicator MI, to operate the processing circuit in an active idle mode for the first data portion DP associated with the FLIT header. The processing circuit may operate in the active idle mode based on the mode indicator MI (operation 5003). Operating in the active idle mode may reduce a power consumed by a physical-layer circuit (e.g., one or more scramblers SCR and/or the AFE circuit 332 (see FIG. 2).

Accordingly, aspects of some embodiments of the present disclosure may provide improvements to D2D communications by enabling active-idle mode control, via header information, of physical-layer circuits for improved power usage.

Example embodiments of the disclosure may extend to the following statements, without limitation:
Statement 1. An example method includes: receiving, by a processing circuit, a flow control unit (FLIT) header including a mode indicator, determining, by the processing circuit and based on the mode indicator, to operate the processing circuit in an active idle mode for a first data portion associated with the FLIT header, and operating, by the processing circuit, in the active idle mode.
Statement 2. An example method includes the method of statement 1, wherein the operating in the active idle mode includes operating a physical-layer circuit of the processing circuit at a reduced power consumption level based on a scrambler circuit or an analog front-end (AFE) circuit of the physical-layer circuit.
Statement 3. An example method includes the method of any of statements 1 and 2, wherein the operating in the active idle mode includes sending, to a physical-layer circuit, information indicating that the first data portion includes non-valid data.
Statement 4. An example method includes the method of any of statements 2-3, wherein the mode indicator corresponds to one or more bit positions in the FLIT header.
Statement 5. An example method includes the method of any of statements 2-4, wherein the mode indicator is encoded by two bit positions in the FLIT header, and the first data portion corresponds to all data chunks associated with the FLIT header.
Statement 6. An example method includes the method of any of statements 2-5, wherein the FLIT header is a 68-byte unit FLIT header, and the first data portion corresponds to 64 bytes of data associated with the FLIT header.
Statement 7. An example method includes the method of any of statements 2-6, wherein the mode indicator is encoded by three bit positions in the FLIT header, and the first data portion corresponds to a first half of all data chunks associated with the FLIT header.
Statement 8. An example method includes the method of any of statements 2-7, wherein a first state of a first bit position of the three bit positions indicates a location of the first data portion.
Statement 9. An example method includes the method of any of statements 2-8, wherein a first state of a first bit position of the three bit positions indicates that the processing circuit is to operate in the active idle mode for the first half of all the data chunks associated with the FLIT header, and a second state of the first bit position of the three bit positions indicates that the processing circuit is to operate in the active idle mode for a second half of all the data chunks associated with the FLIT header.
Statement 10. An example method includes the method of any of statements 2-9, wherein the FLIT header is a 256-byte unit FLIT header, and the first data portion corresponds to 124 bytes of data associated with the FLIT header.
Statement 11. An example system for performing the method of any of statements 1-10 includes a system including a first die, and a second die connected to the first die, wherein the first die is configured to perform the method of any of statements 1-10.

While embodiments of the present disclosure have been particularly shown and described with reference to the embodiments described herein, it will be understood by those of ordinary skill in the art that various changes in form and details may be made therein without departing from the spirit and scope of the present disclosure as set forth in the following claims and their equivalents.

What is claimed is:

1. A method for performing die-to-die communications, the method comprising:
receiving, by a processing circuit, a flow control unit (FLIT) header comprising a mode indicator;
determining, by the processing circuit and based on the mode indicator, to operate the processing circuit in an active idle mode for a first data portion associated with the FLIT header; and
operating, by the processing circuit, in the active idle mode.

2. The method of claim 1, wherein the operating in the active idle mode comprises operating a physical-layer circuit of the processing circuit at a reduced power consumption level based on a scrambler circuit or an analog front-end (AFE) circuit of the physical-layer circuit.

3. The method of claim 1, wherein the operating in the active idle mode comprises sending, to a physical-layer circuit, information indicating that the first data portion comprises non-valid data.

4. The method of claim 1, wherein the mode indicator corresponds to one or more bit positions in the FLIT header.

5. The method of claim 4, wherein:
the mode indicator is encoded by two bit positions in the FLIT header; and
the first data portion corresponds to all data chunks associated with the FLIT header.

6. The method of claim 5, wherein:
the FLIT header is a 68-byte unit FLIT header; and
the first data portion corresponds to 64 bytes of data associated with the FLIT header.

7. The method of claim 4, wherein:
the mode indicator is encoded by three bit positions in the FLIT header; and
the first data portion corresponds to a first half of all data chunks associated with the FLIT header.

8. The method of claim 7, wherein a first state of a first bit position of the three bit positions indicates a location of the first data portion.

9. The method of claim 7, wherein:
a first state of a first bit position of the three bit positions indicates that the processing circuit is to operate in the active idle mode for the first half of all the data chunks associated with the FLIT header; and
a second state of the first bit position of the three bit positions indicates that the processing circuit is to operate in the active idle mode for a second half of all the data chunks associated with the FLIT header.

10. The method of claim 7, wherein:
the FLIT header is a 256-byte unit FLIT header; and
the first data portion corresponds to 124 bytes of data associated with the FLIT header.

11. A system comprising:
a first die; and
a second die connected to the first die, wherein the first die is configured to perform:
receiving, by a processing circuit of the first die, a flow control unit (FLIT) header comprising a mode indicator;
determining, by the processing circuit of the first die and based on the mode indicator, to operate the processing circuit in an active idle mode for a first data portion associated with the FLIT header; and
operating, by the processing circuit, in the active idle mode.

12. The system of claim 11, wherein the operating in the active idle mode comprises operating a physical-layer circuit of the processing circuit at a reduced power consumption level based on a scrambler circuit or an analog front-end (AFE) circuit of the physical-layer circuit.

13. The system of claim 11, wherein the operating in the active idle mode comprises sending, to a physical-layer circuit, information indicating that the first data portion comprises non-valid data.

14. The system of claim 11, wherein the mode indicator corresponds to one or more bit positions in the FLIT header.

15. The system of claim 14, wherein:
the mode indicator is encoded by two bit positions in the FLIT header; and
the first data portion corresponds to all data chunks associated with the FLIT header.

16. The system of claim 14, wherein:
the mode indicator is encoded by three bit positions in the FLIT header; and
the first data portion corresponds to a first half of all data chunks associated with the FLIT header.

17. The system of claim 16, wherein:
a first state of a first bit position of the three bit positions indicates that the processing circuit of the first die is to operate in the active idle mode for the first half of all the data chunks associated with the FLIT header; and
a second state of the first bit position of the three bit positions indicates that the processing circuit of the first die is to operate in the active idle mode for a second half of all the data chunks associated with the FLIT header.

18. A device comprising:
a processing circuit; and
a memory storing instructions that, based on being executed by the processing circuit, cause the processing circuit to perform:
receiving, by the processing circuit, a flow control unit (FLIT) header comprising a mode indicator;
determining, by the processing circuit and based on the mode indicator, to operate the processing circuit in an active idle mode for a first data portion associated with the FLIT header; and
operating, by the processing circuit, in the active idle mode.

19. The device of claim 18, wherein the operating in the active idle mode comprises operating a physical-layer circuit of the processing circuit at a reduced power consumption level based on a scrambler circuit or an analog front-end (AFE) circuit of the physical-layer circuit.

20. The device of claim 18, wherein the operating in the active idle mode comprises sending, to a physical-layer circuit, information indicating that the first data portion comprises non-valid data.
